(19) United States
(12) Patent Application Publication
(10) Pub. No.: US 2026/0181919 A1
(43) Pub. Date: Jun. 25, 2026

(54) METHODS, APPARATUSES, AND SYSTEMS FOR THIN FILM RESISTORS

(71) Applicant: STMicroelectronics International N.V., Geneva (CH)

(72) Inventors: Alessia AZZOPARDO, Milano (IT); Samuele SCIARRILLO, Usmate Velate (IT); Paolo COLPANI, Agrate Brianza (IT)

(21) Appl. No.: 18/999,616

(22) Filed: Dec. 23, 2024

(51) Int. Cl. H10D 1/00; H01L 23/528; H01L 23/58; H10D 1/47

(52) U.S. Cl. CPC H10D 1/021; H10D 1/47; H10W 20/43; H10W 42/00

(57) ABSTRACT

Methods, apparatuses, and systems for thin film resistors (TFRs) are provided. An example method includes a semiconductor structure with a device area and resistor area. The resistor area includes thin film resistor patterning. A dielectric layer is formed over the device area and the resistor area. The dielectric layer is planarized. In a first embodiment, the dielectric layer is etched over the device area. In a second embodiment, the dielectric layer over the device area has a via formed in it. A metal deposition layer is deposited. The metal deposition layer is etched to form a metal layer and expose the TFRs.

### TECHNOLOGICAL FIELD

Example embodiments of the present disclosure relate generally to thin film resistors, particularly to manufacturing thin film resistors.

### BACKGROUND

Thin film resistors (TFRs) are used in semiconductor devices for their accuracy, stability, reliability, and adaptability, which are vital for high-performance electronic circuits. Applications using TFRs include electronic measuring systems, monitoring equipment, audio applications, precision controls, and instrumentation.

TFRs are produced by applying a thin resistive material layer onto an insulating base or surface. Multiple TFRs may be spaced separately from each other by a distance. However, forming TFRs presents problems when the TFRs are spaced close together at smaller distances. In particular, and with conventional manufacturing techniques, there is a problem of residues that are present during the patterning of metal layer(s) that are on the same or similar layers or surfaces as TFRs. Residue(s) of the metal layer are left in small spaces between the TFRs.

Conventional operations for the patterning of the TFRs and adjacent protective spacers are completed prior to a deposition of a metal layer. After this metal layer is deposited, it must be removed, including from between the TFRs and adjacent protective spacers. Removal of this metal layer is difficult, particularly with small spacing between TFRs. The metal layer will oxidize during lithographic steps, which causes etch stop phenomena that lead to residues after removing the metal layer. The resulting metal residues between adjacent TFRs may reach heights up to several microns. The residues may also be harmful both to the TFRs (leading to short circuits) and to the final passivation layer (leading to damage to its integrity).

The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to methods, apparatuses, and systems for thin film resistors (TFRs), particularly to manufacturing TFRs.

In accordance with some embodiments of the present disclosure, an example manufacturing method of an electronic device is provided. The manufacturing method comprises: providing a semiconductor substrate comprising a device area and a resistor area, forming a back-end-of-line (BEOL) module overlapping the semiconductor substrate by: forming, at both the device area and the resistor area, a first dielectric layer on the semiconductor substrate; forming, at both the device area and the resistor area, a first metal layer on the first dielectric layer, the first metal layer comprising a plurality of metal portions; forming, at both the device area and the resistor area, a second dielectric layer on the first metal layer; forming, at the resistor area, a first thin film resistor (TFR) element and second TFR element on the second dielectric layer, the first TFR element and the second TFR element are arranged with a gap between the first TFR element and the second TFR element, the each of the first TFR element and the second TFR element are electrically contacting one or more respective metal portions of the first metal layer, and each of the first TFR element and the second TFR element comprise a respective resistive layer and an insulating layer in contact with, and on, the respective resistive layer; forming, at the resistor area, a third dielectric layer comprising: a first sub-layer made of a first dielectric material covering both the first TFR element and the second TFR element and a portion of the second dielectric layer at the gap; and a second sub-layer made of a second dielectric material covering the portion of the second dielectric layer interposed between the first TFR element and the second TFR element; a thickness of a first assembly of the first sub-layer and second sub-layer and a respective thickness of a second assembly of the first TFR element and the first sub-layer covering the TFR element are both within a range centered in a nominal thickness value and having −10% of the nominal thickness value as a minimum, and +10% of the nominal thickness value as a maximum; depositing, at both the device area and the resistor area, a metal deposition layer; and etching, at both the device area and the resistor area, the metal deposition layer to form, at the device area, a second metal layer, and, at the resistor area, a plurality of protective structures originating from the third dielectric layer, the plurality of protective structures collectively cover each sidewall of the first TFR element and of the second TFR element as well as the gap between the first TFR element and the second TFR element.

In some embodiments, the manufacturing method further comprises, before forming the first TFR element and the second TFR element, forming a first vias for electrically contacting each of the first TFR element and the second TFR element to one or more respective metal portions of the first metal layer.

In some embodiments, the manufacturing method further comprises, before forming the first TFR element and the second TFR element, forming a second via for electrically contacting the second metal layer to one or more metal portions of the first metal layer, the second via passes through the second dielectric layer, and the second metal layer is on the second dielectric layer.

In some embodiments, forming the third dielectric layer comprises: i) at both the device area and the resistor area, depositing the first sub-layer; ii) at both the device area and the resistor area, depositing the second sub-layer covering the first sub-layer over both the first TFR element and the second TFR element and the portion of the second dielectric layer at the gap; and iii) planarizing the second sub-layer at a level corresponding to the thickness of both the first assembly and the second assembly.

In some embodiments, forming the third dielectric layer further comprises, after planarizing the second sub-layer, removing the third dielectric layer at the device area.

In some embodiments, forming the third dielectric layer further comprises, after planarizing the second sub-layer, leaving the third dielectric layer at the device area.

In some embodiments, the manufacturing method further comprises, before depositing the metal deposition layer, forming a via for electrically contacting the second metal layer to a respective metal portion of the first metal layer, the via passes through the second dielectric layer and the third dielectric layer, and the second metal layer is on the third dielectric layer.

In some embodiments, the first metal layer and the second metal layer comprises aluminum.

In some embodiments, the resistive layer comprises a SiCr layer and the insulating layer comprises a SiN layer.

In some embodiments, the BEOL module comprises a number N of metal layers, an N-th metal layer is the farthermost from the semiconductor substrate, and the second metal layer is the N-th metal layer.

In accordance with some embodiments of the present disclosure, an example semiconductor structure is provided. The semiconductor structure comprises: a semiconductor substrate comprising a device area and a resistor area, a back-end-of-line (BEOL) module overlapping the semiconductor substrate and comprising: at both the device area and the resistor area, a dielectric layer on the semiconductor substrate; at both the device area and the resistor area, a first metal layer comprising a plurality of metal portions, the first metal layer positioned in the dielectric layer at a first height; at the resistor area, a first thin film resistor (TFR) element and second TFR element, the first TFR element and the second TFR element are arranged with a gap between the first TFR element and the second TFR element, the each of the first TFR element and the second TFR element are electrically contacting one or more respective metal portions of the first metal layer, each of the first TFR element and the second TFR element comprise a respective resistive layer and an insulating layer in contact with, and on, the respective resistive layer, and the first TFR element and the second TFR element are positioned in the dielectric layer at a second height greater than the first height; at the device area, a second metal layer electrically contacting respective portions of the first metal layer and positioned at the second height; and at the resistor area, a plurality of protective structures, the plurality of protective structures collectively cover each sidewall of the first TFR element and of the second TFR element as well as the gap between the first TFR element and the second TFR element.

In some embodiments, the protective structures and the first TFR element and the second TFR element have substantially a flat surface.

In some embodiments, the semiconductor structure further comprises: first vias for electrically contacting each of the first TFR element and the second TFR element with one or more of the metal portions of the first metal layer; a second via for electrically contacting the second metal layer and one or more metal portions of the first metal layer; and the first vias and the second via have a same height.

In some embodiments, the first metal layer and the second metal layer comprise aluminum.

In some embodiments, the BEOL module comprises a number N of metal layers, an N-th metal layer is the farthermost from the semiconductor substrate, and the second metal layer is the N-th metal layer.

In accordance with some embodiments of the present disclosure, a second example semiconductor structure is provided. This semiconductor structure comprises: a semiconductor substrate comprising a device area and a resistor area, a back-end-of-line, BEOL, module overlapping the semiconductor substrate and comprising: at both the device area and the resistor area, a dielectric layer on the semiconductor substrate; at both the device area and the resistor area, a first metal layer comprising a plurality of metal portions, the first metal layer positioned in the dielectric layer at a first height; at the resistor area, a first thin film resistor (TFR) element and second TFR element, the first TFR element and the second TFR element are arranged with a gap between the first TFR element and the second TFR element, the each of the first TFR element and the second TFR element are electrically contacting one or more respective metal portions of the first metal layer, each of the first TFR element and the second TFR element comprise a respective resistive layer and an insulating layer in contact with, and on, the respective resistive layer, and the first TFR element and the second TFR element are positioned in the dielectric layer at a second height greater than the first height; at the device area, a second metal layer electrically contacting respective portions of the first metal layer and positioned at a third height greater than the second height; and at the resistor area, a plurality of protective structures, the plurality of protective structures collectively cover each sidewall of the first TFR element and of the second TFR element as well as the gap between the first TFR element and the second TFR element.

In some embodiments, the protective structures and the first TFR element and the second TFR element have substantially a flat surface.

In some embodiments, the semiconductor structure further comprises: first vias for electrically contacting each of the first TFR element and the second TFR element with one or more of the metal portions of the first metal layer; a second via for electrically contacting the second metal layer and one or more metal portions of the first metal layer; and the first vias are shorter than the second via.

In some embodiments, the first metal layer and the second metal layer comprise aluminum.

In some embodiments, the BEOL module comprises a number N of metal layers, an N-th metal layer is the farthermost from the semiconductor substrate, and the second metal layer is the N-th metal layer.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

Having thus described certain example embodiments of the present disclosure in general terms, reference will now be made to the accompanying drawings, which are not necessarily drawn to scale, and wherein:

FIGS. 1A, 1B, and 1C illustrate exemplary cross-section views of a semiconductor structure in accordance with one or more embodiments of the present disclosure;

FIGS. 2A-2F illustrate exemplary cross-section views of various operations in forming a semiconductor structure in accordance with one or more embodiments of the present disclosure;

FIG. 3 illustrates a flowchart of example operations for forming a semiconductor structure in accordance with one or more embodiments of the present disclosure;

FIGS. 4A-4F illustrate exemplary cross-section views of various operations in forming a semiconductor structure in accordance with a first embodiment of the present disclosure;

FIG. 5 illustrates a flowchart of example operations for forming a semiconductor structure in accordance with a first embodiment of the present disclosure;

FIGS. 6A-6F illustrate exemplary cross-section views of various operations in forming a semiconductor structure in accordance with a second embodiment of the present disclosure; and

FIG. 7 illustrates a flowchart of example operations for forming a semiconductor structure in accordance with a second embodiment of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

### Overview

Various embodiments described herein relate to methods, apparatuses, and systems for thin film resistors (TFRs), particularly to manufacturing TFRs. TFR patterning may allow for placing TFRs, including for connecting two or more TFRs in parallel and/or series, such as through using vias to a different metal layers. Forming TFRs as described herein may provide for elimination or reduction of residue(s) between TFRs during back-end-of-line processes or operations.

The elimination or reduction of residue increases effectiveness of TFRs by allowing TFR patterning to be closer distances. This may allow for more TFRs to be placed closer together. It may allow for creating the longest resistive path in a smallest possible area and/or reduce the footprint of one or more components on a die. Regardless of the patterning, adjacent TFRs have to be laterally insulated with dielectrics protective spacers or protective spacers to avoid short-circuits among the adjacent TFRs. Embodiments of the present disclosure provide for TFRs to be located closer together by minimizing and/or eliminating metal residues in manufacturing of semiconductor structures.

The present disclosure allows for reduction of residue by eliminating spaces in which residues conventionally form. For example, the present disclosure does not require a patterning step or operation for protective spacers before depositing and patterning a metal layer. In contrast, embodiments of the present disclosure eliminate spaces in which metal residues form by filing these spaces with one or more materials, such as a dielectric layer. This dielectric layer allows to reduce the unevenness of the free surface of the device on which the metal layer is deposited. In this way, the deposited metal layer will not create accentuated ridges and valleys but will have a flatter overall distribution. This will allow a more uniform patterning (i.e., definition) of the metal layer, avoiding metal residues even in presence of very low pitch TFRs.

In various embodiments, the TFR patterning of TFR elements is a pattern of a resistive layer (a.k.a., thin film layer) covered by an insulating layer (a.k.a., hard mask layer). In various embodiments, resistive layer (e.g., a thin film resistive layer) may be made of silicon chromium (SiCr) that forms a SiCr layer. In various embodiments, the insulating layer 144 (e.g., hard mask layer) may be made of silicon nitride (SiN).

During manufacturing of integrated circuits with TFRs, a semiconductor material wafer may have a first side, front side, or front end with active components (e.g., capacitor, transistors, diodes, etc.) and then connect these components or active elements with a stack configuration of oxide and metal layers and the like. The stack configuration is arranged above the front side with the active components interposed between the stack configuration and the substrate. The stack configuration commonly is named back-end-of-line (BEOL) of the device. In various embodiments, the back end of line may be provided with, for example, TFRs in a BEOL module. Additionally, various embodiments may also include capacitors on the same side and/or surface as the TFRs in a BEOL module. Operations performed on this back end of the stack for forming a BEOL module are referred to as back end of line (BEOL) processes or operations. Formations of TFRs in accordance with one or more embodiments of the present disclosure are BEOL processes or operations.

### Exemplary Systems, Apparatuses, and Methods

Embodiments of the present disclosure herein include methods, apparatuses, and systems for TFRs, particularly to manufacturing TFRs.

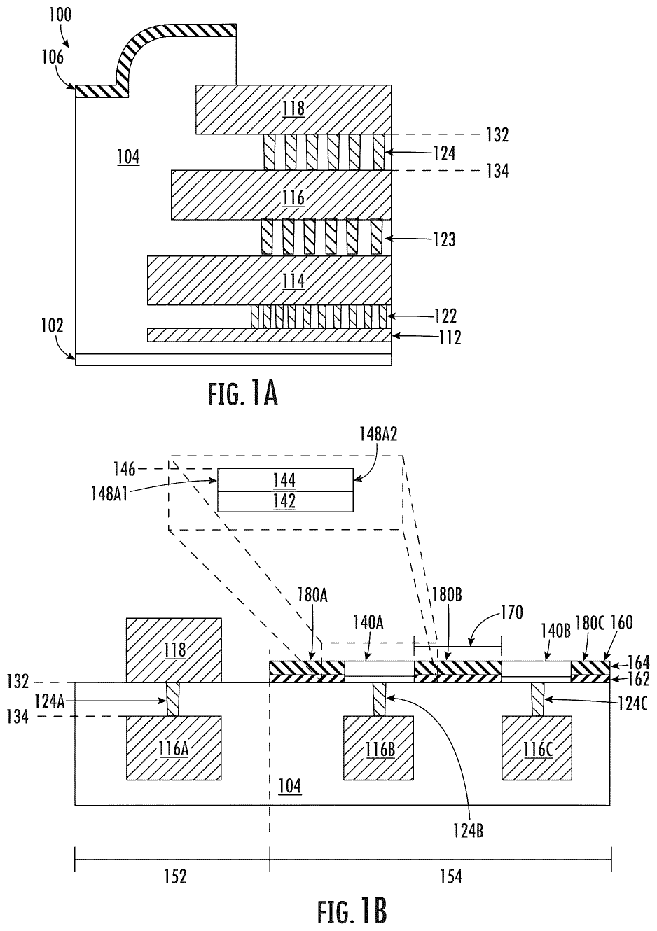

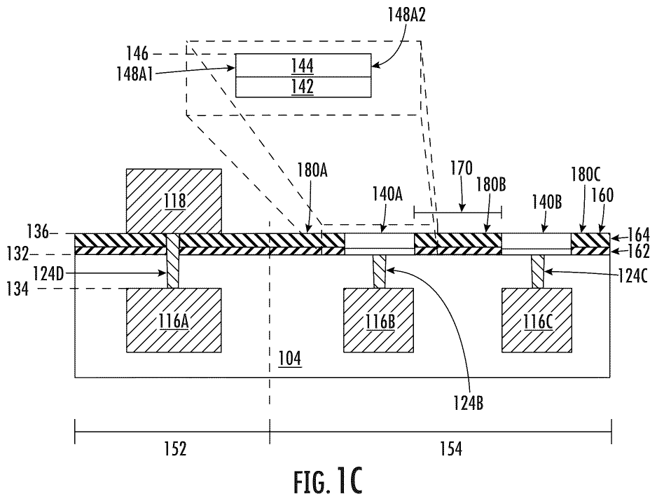

FIGS. 1A, 1B, and 1C illustrate exemplary cross-section views of a semiconductor structure in accordance with one or more embodiments of the present disclosure.

FIG. 1A illustrates an exemplary cross-section view of a semiconductor structure in accordance with one or more embodiments of the present disclosure. The semiconductor structure 100 may include a substrate 102, a dielectric layer 104 (over the substrate 102), a passivation layer 106, a pre-metal layer 112 connected by one or more vias 122 to a metal layer 114, the metal layer 114 connected to a metal layer 116 by one or more vias 123, and metal layer 116 connected by one or more vias 124 to a metal layer 118. In various embodiments, the dielectric layer 104 may be formed from multiple dielectric layers, such as a first dielectric layer 104A and a second dielectric layer 104 as described herein, which may each be made of the same material and formed during separate operations. In various embodiments, the metal layer 114 may be referred to as a first metal layer 114, the metal layer 116 may be referred to as a second metal layer 116, and the metal layer 118 may be referred to as a third metal layer 118 or final metal layer (e.g., the final metal layer of a BEOL process). The number of metal layers is purely exemplary, with the semiconductor substrate that may comprise any number of metal layers (e.g., more than 1 and less than 15, which in various embodiments may use 3-7 metal levels in the BEOL module). The semiconductor structure 100 illustrated may be back-end-of-line (BEOL) portion of a semiconductor device.

The bottom of the metal layer 118 may be located at a first level 132. The top of the metal layer 116 may be located at second level 134.

In various embodiments, the metal layers 112, 114, 116, and 118 may comprise aluminum, such as, for example, aluminum copper (AlCu). The vias 122, 123, 124 may be made of a conductive material, such as, for example, tungsten (W). Thus, and as illustrated, the one or more metal layers may be electrically contacting each other with the one or more vias 122, 123, 124.

FIG. 1B illustrates an exemplary cross-section view of a semiconductor structure in accordance with a first embodiment of the present disclosure. The cross-section view may be of a portion of a BEOL module. The BEOL module includes a number N of metal layers (e.g., 116, 118), wherein the N-th metal layer is the farthermost from the semiconductor substrate. In various embodiments, metal layer 118 is this N-th metal layer. This exemplary cross-section view illustrates a dielectric layer 104 that has a device area 152 and a resistor area 154. The dielectric layer 104 may be referred to as an intermetal dielectric (IMD) layer. The device area 152 may be where one or more active components (e.g., capacitor, transistors, diodes, etc.) may be defined on the substrate 102. The resistor area 154 may be where the TFR elements 140 (e.g., a first TFR element 140A, a second TFR element 140B) are located. There may be a gap 170 between each of the TFR elements 140 (e.g., gap 170 is between the first TFR element 140A and the second TFR element 140B). A plurality of protective structures 180 (e.g., 180A, 180B, 180C) surround the sidewalls 148 (e.g., 148A1, 148A2) of the TFR elements 140 and cover or fill in the gap 170. It will be appreciated that some active components may be present on a front side of the substrate 102 even at the resistor area 154. However, the TFR elements 140 are only located in the BEOL module at the resistor area 154 and not at the device area 152. The TFR elements 140 collectively may be referred to as a TFR patterning. While FIG. 1B illustrates a cross-section view with two TFRs, it will be appreciated that additional TFR elements 140A, 140B beyond the two illustrated are included in embodiments of the present disclosure.

In the first embodiment the TFR elements 140 and the metal layer 118 are both located on the first level 132. A first metal layer 116 may have a plurality of metal portions (e.g., 116A, 116B, 116C). Vias 124 may electrically connect one or more portions of the metal layer 116 to one or more portions of the metal layer 118 and one or more portions of the TFR elements 140 (in particular, the respective thin film resistive layer 142 of the TFR element 140). For example, a first via 124A may electrically connect a top portion of the metal layer 116A at second level 134 to the bottom of the metal layer 118 at a first level 132. A second via 124B may electrically connect a top portion of the metal layer 116B at second level 134 to the bottom of a first TFR element 140A at a first level 132. A third via 124C may electrically connect a top portion of the metal layer 116C at second level 134 to the bottom of a second TFR element 140B at a first level 132.

In various embodiments, the second level 134 is a lowest level may be referred to as a first height and the first level 132 is a higher level and may be referred to as a second height that is greater than the first height.

FIG. 1C illustrates an exemplary cross-section view of a semiconductor structure in accordance with a second embodiment of the present disclosure. The cross-section view may be of a portion of a BEOL module. The BEOL module includes a number N of metal layers (e.g., 116, 118), wherein the N-th metal layer is the farthermost from the semiconductor substrate. In various embodiments, metal layer 118 is this N-th metal layer. This exemplary cross-section view illustrates a dielectric layer 104 that has a device area 152 and a resistor area 154. The dielectric layer 104 may be referred to as an intermetal dielectric (IMD) layer. The device area 152 may be where one or more active components (e.g., capacitor, transistors, diodes, etc.) may be defined on the substrate 102. The resistor area 154 may be where the TFR elements 140 (e.g., e.g., a first TFR element 140A, a second TFR element 140B) are located. There may be a gap 170 between each of the TFR elements 140 (e.g., gap 170 is between the first TFR element 140A and the second TFR element 140B). A plurality of protective structure 180 (e.g., 180A, 180B, 180C) surround the sidewalls 148 (e.g., 148A1, 148A2) of the TFR elements 140 and cover or fill in the gap 170. It will be appreciated that some active components may be present on a front side of the substrate 102 even at the resistor area 154. However, the TFR elements 140 are only located in the BEOL module at the resistor area 154 and not at the device area 152. The TFR elements 140 collectively may be referred to as a TFR patterning. While FIG. 1C illustrates a cross-section view with two TFR elements 140A, 140B, it will be appreciated that additional TFR elements 140 beyond the two illustrated are included in embodiments of the present disclosure.

In the second embodiment, the TFR elements 140 are located on the first level 132 and the metal layer 118 is located on a third level 136. A first metal layer 116 may have a plurality of metal portions (e.g., 116A, 116B, 116C). The third level 136 is above the first level 132. The third level is located on top of the third dielectric layer 160. Vias 124 may electrically connect one or more portions of the metal layer 116 to one or more portions of the metal layer 118 and one or more portions of the TFR elements 140 (in particular, the respective thin film resistive layer 142 of the TFR element 140). For example, a via 124D may electrically connect a top portion of the metal layer 116A at second level 134 to the bottom of the metal layer 118 at a third level 136. A second via 124B may electrically connect a top portion of the metal layer 116B at second level 134 to the bottom of a first TFR element 140A at a first level 132. A third via 124C may electrically connect a top portion of the metal layer 116C at second level 134 to the bottom of a second TFR element 140B at a first level 132. The via 124D may be larger or longer than one or more other vias 124 connecting to the metal layer 116. For example, the second via 124B and the third via 124C are shorter than the via 124D.

In various embodiments, a TFR element 140 may be surrounded by a third dielectric layer 160. The third dielectric layer 160 is comprised of a first dielectric sub-layer 162 of a first dielectric material, for example a SiN layer (e.g., having a thickness greater than or equal to 30 nm and less than or equal to 70 nm, for example equal to about 50 nm) that is covered by a second dielectric sub-layer 164, for example an oxide layer (e.g., having a thickness greater than or equal to 200 nm and less than or equal to 800 nm, for example equal to about 500 nm), which may be referred to as a SiN/oxide layer. In various embodiments, the first sub-layer 162 is deposited first and then the second sub-layer 164 is deposited over the first sub-layer 162. The third dielectric layer 160 may cover the first level 132 of the resistor area 154 where there are no TFR elements 140.

In conventional semiconductor devices, a protective spacer may be between the TFR elements 140. In various embodiments of the present disclosure, there are no protective spacers. Instead, there is a third dielectric layer 160 that continuously fills the free gap(s) 170 between the TFR elements 140.

In various embodiments of the present disclosure (for example with reference to FIG. 1B), the third dielectric layer 160 is not under the metal layer 118 or, more in general, in the device area 152. The first level 132 of the device area 152 may be exposed. In various embodiments, the TFR elements 140 are on the same level as the metal layer 118, and vias 124 are electrically connected to the TFR elements 140 and the metal layer 118 from below. The vias 124 may all be the same height.

In various embodiments of the present disclosure (for example with reference to FIG. 1C), the third dielectric layer 160 lies under the metal layer 118 and, more in general, also covers the device area 152. The first level 132 of the device area 152 is covered by the third dielectric layer 160. The TFR elements 140 are on the first level 132, while the metal layer 118 is on a higher third level 136. The vias 124 are electrically connected to the TFR elements 140 and the metal layer 118 from below, but the via contacting the metal layer 118 extends higher than those contacting the TFR elements 140 (since it extends through also the third dielectric layer 160).

In various embodiments, a TFR element 140 may be surrounded by one or more protective structures 180 (e.g., 180A, 180B, 180C). The one or more protective structures 180 may be located on or around the sidewall 148 (e.g., 148A1, 148A2) of a TFR element 140 (e.g., 140A). A TFR element 140 may be made of resistive layer 142 (a.k.a. thin film layer) that is covered with an insulating layer 144 (a.k.a. hard mask layer). In various embodiments, the resistive layer 142 may be made of silicon chromium (SiCr) that forms a SiCr layer. In various embodiments, the insulating layer 144 may be made of silicon nitride (SiN). A protective structure 180 (e.g., 180A, 180B, 180C) may originate from a third dielectric layer 160 that includes a first sub-layer 162, which may be a SiN layer, covered by a second sub-layer 164, which may be an oxide layer. A protective structure may protect some or all of the TFR element 140 from oxidation and prevent exposure to one or more external processes or operations. It will be appreciated that FIGS. 1B and 1C are a cross-section views and that a protective structure 180 may surround a TFR element 140. Thus, while a protective structure 180 is illustrated as multiple protective structures 180A, 180B, 180C to the left and right of TFR elements 140A, 140B, these may be considered one protective structure that may surround the TFR elements 140A, 140B.

In various embodiments, the second level 134 is a lowest level may be referred to as a first height. The first level 132 is a higher level than the second level and may be referred to as a second height that is greater than the first height. The third level 136 is a higher level than the first level 132 and the second level 134, and the third level 136 may be referred to as a third height that is greater than the first height and/or the second height.

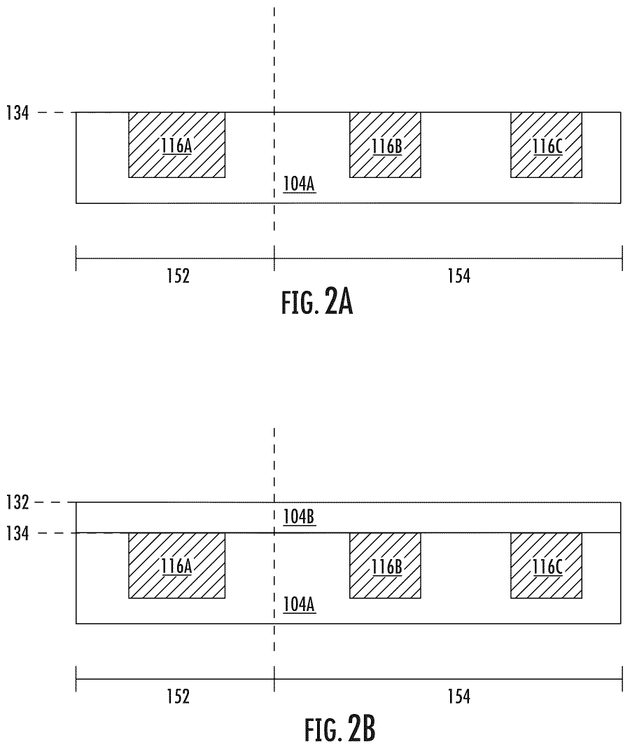

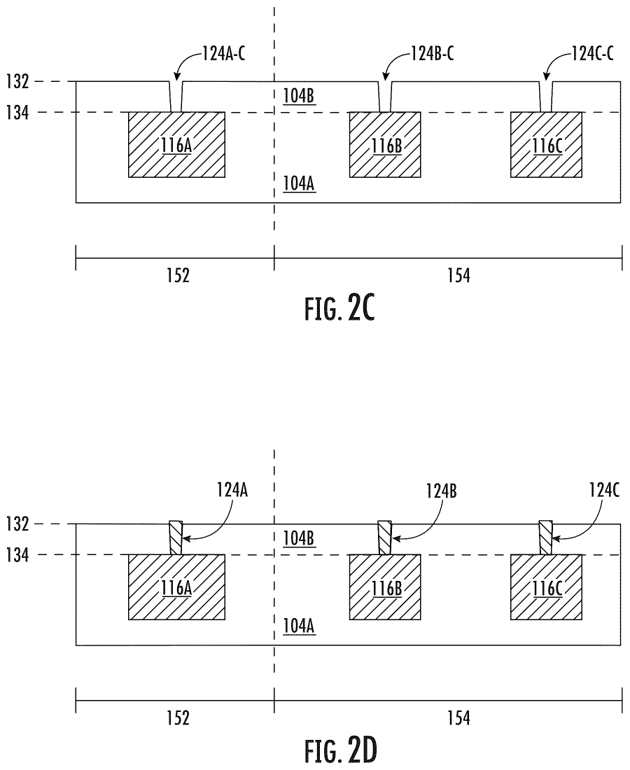

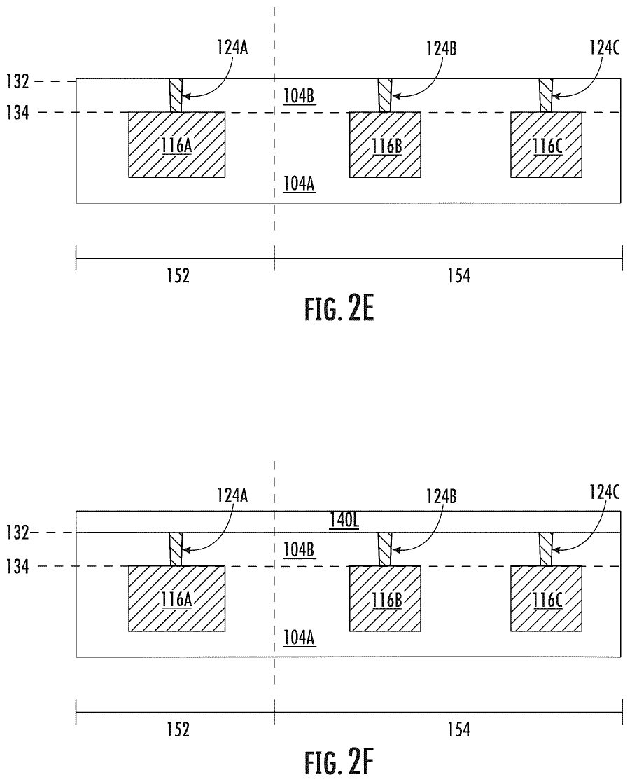

FIGS. 2A-2F illustrate exemplary cross-section views of various operations in forming a semiconductor structure in accordance with one or more embodiments of the present disclosure. The semiconductor structure may be a part of an electronic device with a back-end-of-line (BEOL) module.

FIG. 2A illustrates a first exemplary cross-section view of an operation in forming a semiconductor structure in accordance with one or more embodiments of the present disclosure. A semiconductor structure is provided with a first dielectric layer 104A with one or more portions of a metal layer 116 (e.g., 116A, 116B, 116C) exposed at the second level 134.

FIG. 2B illustrates a first exemplary cross-section view of an operation in forming a semiconductor structure in accordance with one or more embodiments of the present disclosure. A second dielectric layer 104B is formed over the second level 134 to a height of the first level 132. The second dielectric layer 104B, when formed over the second level 134, covers the device area 152 and the resistor area 154 so that the first dielectric layer 104A and the one or more portions one or more portions of a metal layer 116 (e.g., 116A, 116B, 116C) are covered. In various embodiments, the second dielectric layer 104B is made of the same material as the first dielectric layer 104A and, once formed, the first dielectric layer 104A and the second dielectric layer 104B may be treated in some embodiments as one dielectric layer 104.

FIG. 2C illustrates a first exemplary cross-section view of an operation in forming a semiconductor structure in accordance with one or more embodiments of the present disclosure. Via cavities 124-C (e.g., 124A-C, 124B-C, 124C-C) for vias 124 (e.g., 124A, 124B, 124c) are formed in the top of the second dielectric layer 104B. The via cavities 124-C are formed at least from the first level 132 to the one or more portions of a metal layer 116 at the second level 134. The via cavities may be formed by patterning.

FIG. 2D illustrates a first exemplary cross-section view of an operation in forming a semiconductor structure in accordance with one or more embodiments of the present disclosure. Vias 124 (e.g., 124A, 124B, 124C) are formed by filling the via cavities 124-C with a via material. In various embodiments, the via material may be tungsten. In various embodiments, the filling of the via cavities 124-C may leave one or more portions of the via material(s) of the vias 124 above the first level 132.

FIG. 2E illustrates a first exemplary cross-section view of an operation in forming a semiconductor structure in accordance with one or more embodiments of the present disclosure. After filling the via cavities 124-C with via material, the top of the structure may be polished (e.g., chemical mechanical polishing operation) at first level 132. This polishing may lower the level of the via material at the mouth or top of via cavities 124-C and avoid overfilling of the vias 124 above the first level 132.

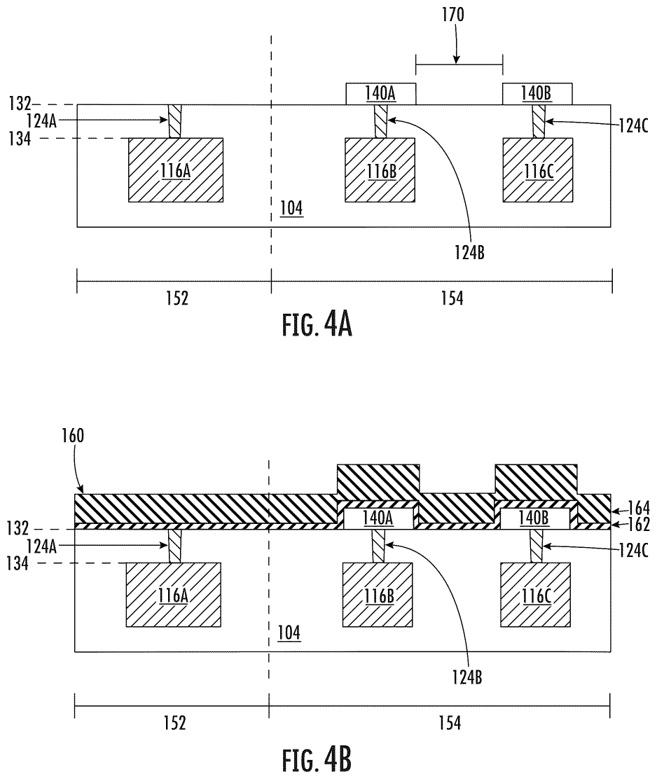

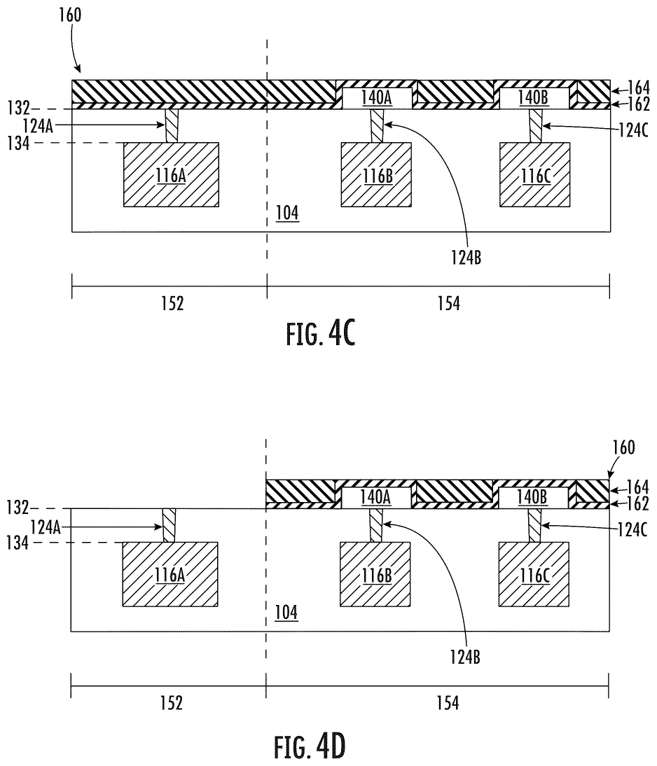

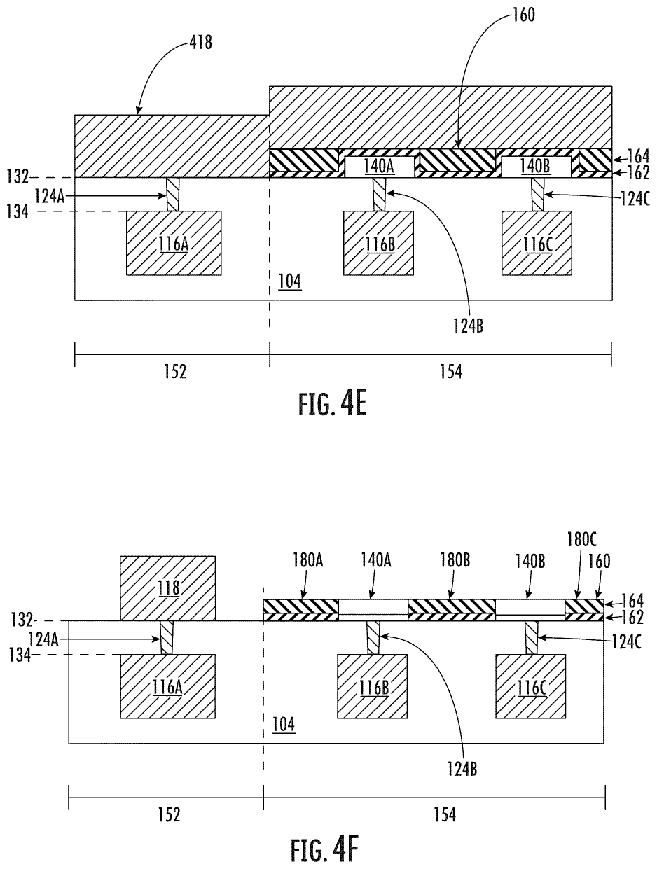

FIG. 2F illustrates a first exemplary cross-section view of an operation in forming a semiconductor structure in accordance with one or more embodiments of the present disclosure. After polishing, a TFR layer 140L is deposited over the structure at the first level 132. In various embodiments, the TFR layer 140L is used to create the TFR elements 140. The deposition of the TFR layer 140L may include deposition of a resistive layer 142 and an insulating layer 144. These may then be collectively patterned to form the TFR elements 140, such as in the embodiments illustrated in FIGS. 4A-4F.

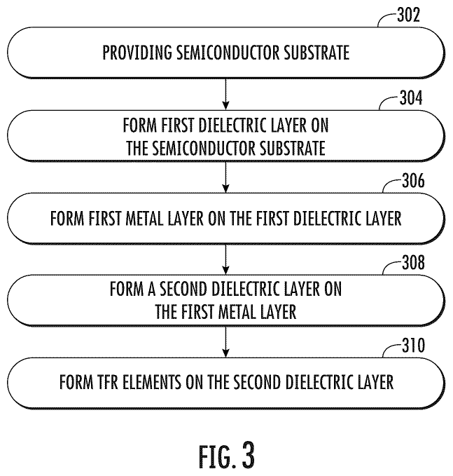

FIG. 3 illustrates a flowchart of example operations for forming a semiconductor structure in accordance with one or more embodiments of the present disclosure. The semiconductor structure may be, or may be part of, an electronic device with a back-end-of-line (BEOL) module.

At operation 302, a semiconductor substrate is provided. The semiconductor substrate includes a device area 152 and a resistor area 154. The semiconductor substrate may be then be provided with a BEOL module. The BEOL module may be overlapping the semiconductor substrate.

At operation 304, a first dielectric layer is formed on the semiconductor substrate. A BEOL module may be formed on the semiconductor substrate. The BEOL module may include first forming a first dielectric layer 104A on the semiconductor substrate. In various embodiments, the BEOL module may already have had one or more additional dielectric layers and/or metal layers formed in the BEOL module on the back of the semiconductor substrate.

At operation 306, a first metal layer is formed on the first dielectric layer. A first metal layer may be formed on the first dielectric layer 104A. The first metal layer 116 may include a plurality of metal portions (e.g., 116A, 116B, 116C). After being formed, the first dielectric layer 104A and the first metal layer 116 with the plurality of metal portions may share top surface at the second level 134. FIG. 2A illustrates various embodiments after the performance of operation 306.

At operation 308, a second dielectric layer is formed on the first metal layer. A second dielectric layer 104B may be formed on the surface of the first dielectric layer 104A and the plurality of metal portions of the first metal layer 116. FIG. 2B illustrates various embodiments after the performance of operation 308.

At operation 310, TFR elements are formed on the second dielectric layer. TFR elements 140 (e.g., 140A, 140B) are formed on the second dielectric layer 104B. In various embodiments, the second dielectric layer 104B may have a plurality of via cavities 124-C formed. The via cavities 124-C may be filled with a via material to form a plurality of vias 124. The forming of the plurality of vias 124 may be by filling the via cavities 124-C with a via material (e.g., tungsten). The filling of the via cavities 124-C may have the via material overflow the top of the second dielectric layer 104B at a first level 132. One or more chemical mechanical polishing operations may be used to remove the overflow material of the vias 124. A TFR layer 140L may be deposited on the first level 132. A plurality of TFR elements 140 (e.g., a first TFR element 140A and a second TFR element 140B) may be formed from the TFR layer 140L by patterning the TFR layer 140L. FIG. 2F illustrates various embodiments after the performance of operation 310.

FIGS. 4A-4E illustrate exemplary cross-section views of various operations in forming a semiconductor structure in accordance with a first embodiment of the present disclosure. The semiconductor structure may be a part of an electronic device with a back-end-of-line (BEOL) module.

FIG. 4A illustrates a first exemplary cross-section view of an operation in forming a semiconductor structure in accordance with a first embodiment of the present disclosure. A TFR patterning with hard mask is provided. The thin film resistor patterning of the TFR layer 140L (e.g., from FIG. 2F) is provided on a semiconductor structure with a first level 132 that includes a metal layer 116 with a second level 134 electrically connected with a plurality of vias 124 (e.g., 124A, 124B, 124C) to the first level 132.

The thin film resistor patterning may include a first TFR element 140A and a second TFR element 140B. Each TFR element 140 (e.g., 140A, 140B) may be comprised of a resistive layer 142 and an insulating layer 144. The resistive layer 142 may be a SiCr layer. The insulating layer 144 may be a SiN layer. The thin film resistor patterning may be electrically connected to one or more portions of a metal layer 116 by one or more vias 124. The TFR patterning occurred after the patterning and formation of the vias 124. A first TFR element 140A of the thin film resistor patterning may be electrically connected with a via 124B to a portion of the metal layer 116B. A second TFR element 140B of the thin film resistor patterning may be electrically connected with a via 124C to a portion of the metal layer 116C. In various embodiments, FIG. 4A is associated with operation 502.

FIG. 4B illustrates a first exemplary cross-section view of an operation in forming a semiconductor structure in accordance with a first embodiment of the present disclosure. A third dielectric layer 160 is deposited over the first surface at the first level 132 and the TFR patterning. In various embodiments, the dielectric layer is comprised of a first sub-layer 162 that is covered by a second sub-layer 164, which may be referred to as a SiN/oxide layer. In various embodiments, the first sub-layer 162 is deposited first and then the second sub-layer 164 is deposited over the first sub-layer 162. In various embodiments, FIG. 4B is associated with operation 504. The thickness of the third dielectric layer 160 at this stage or operation is thicker than the TFR element 140. In particular, the second sub-layer 164, at this stage, has a thickness above 800 nm, preferably above 1000 nm.

FIG. 4C illustrates a first exemplary cross-section view of an operation in forming a semiconductor structure in accordance with a first embodiment of the present disclosure. The third dielectric layer 160 is planarized. The planarization may be by chemical mechanical polishing (CMP). The planarization flattens the surface of the oxide layer while exposing the first sub-layer 162 above the top of the thin film resistors 140. In various embodiments, the planarization may expose the thin film resistor patterning. In various embodiments, FIG. 4C is associated with operation 506.

In various embodiments, after planarization, the first sub-layer 162 and second sub-layer 164 in the gaps between TFRs may be a first assembly of one or more portions of the resistor area 154 and a TFR element 140 and the first sub-layer 162 covering the TFR element 140 may be a second assembly. In various embodiments, a thickness of the first assembly and a respective thickness of the second assembly are both equal or within a range centered in a nominal thickness value and having −10% (preferably −5%) of the nominal thickness value as a minimum, and +10% (preferably +5%) of the nominal thickness value as a maximum. The first sub-layer may be made of a first dielectric material and the second sub-layer may be made of a second dielectric material.

FIG. 4D illustrates a first exemplary cross-section view of an operation in forming a semiconductor structure in accordance with a first embodiment of the present disclosure. The third dielectric layer 160 of the device area may be etched to remove the third dielectric layer 160. Thus, the third dielectric layer 160 is etched outside the resistor area 154. In various embodiments, FIG. 4D is associated with operation 508.

The etching of the third dielectric layer 160 may be performed by masking the resistor area with TFR patterning with a mask. An etch may be performed to remove the third dielectric layer 160 from the device area 152 to expose the surface at the first level 132 and the via(s) (e.g., 124A) of the device area 152.

Consequently, as illustrated in FIG. 4D, the third dielectric layer 160 remains in the gaps between the TFR elements 140 completely filling the spaces among them. This creates a flat and even top surface of the semifinished product in the resistor area (thanks also to the planarization step disclosed with reference to FIG. 4C).

FIG. 4E illustrates a first exemplary cross-section view of an operation in forming a semiconductor structure in accordance with a first embodiment of the present disclosure. A metal deposition layer 418 may be deposited over both the device area 152 and the resistor area 154. The metal deposition layer is deposited with the same thickness across both areas. The deposition of the metal deposition layer 418 over the resistor area 154 includes the metal layer 418 being layered over the third dielectric layer 160 of the resistor area 154. The metal deposition layer 418 may be deposited to have a flat surface since the below surface is flat. In various embodiments, FIG. 4E is associated with operation 510.

FIG. 4F illustrates a first exemplary cross-section view of an operation in forming a semiconductor structure in accordance with a first embodiment of the present disclosure. The metal layer 418 is etched to form the metal layer 118. The metal layer 118 is electrically connected from below to the metal layer 116A by via 124A. Additionally, the metal etch may remove the residual portion of the third dielectric layer 160 above the TFR elements 140 as well as remove some of the third dielectric layer 160 in the resistor area 154 not above the TFR elements 140 (i.e., overall reduction of the thickness of layer 164 and TFR element 140 with respect to the situation shown in FIG. 4E). In various embodiments, FIG. 4F is associated with operation 512.

The metal layer 118 is formed by the etching of metal deposition layer 418. The etch operation removes the metal deposition layer 418 in the resistor area 154 and the first sub-layer 162 and/or the second sub-layer 164 above the TFR elements 140A, 140B. In various embodiments, the etch may create the dielectric layer between one or more TFR elements 140 being flat. Alternatively, or additionally, the etch may create the dielectric layer between one or more TFR elements 140 being concave.

The TFR elements 140 may be surrounded by one or more protective structures 180 (e.g., 180A, 180B, 180C). The one or more protective structures 180 may be located on or around the sidewalls 148 (e.g., 148A1, 148A2) of a TFR element 140 (e.g., 140A). The plurality of protective structures may be originating from the third dielectric layer 160. The plurality of protective structures 180A, 180B, 180C collectively cover each of the sidewalls of the first TFR element 140A and of the second TFR element 140B as well as the gap 170 between the first TFR element 140A and the second TFR element 140B.

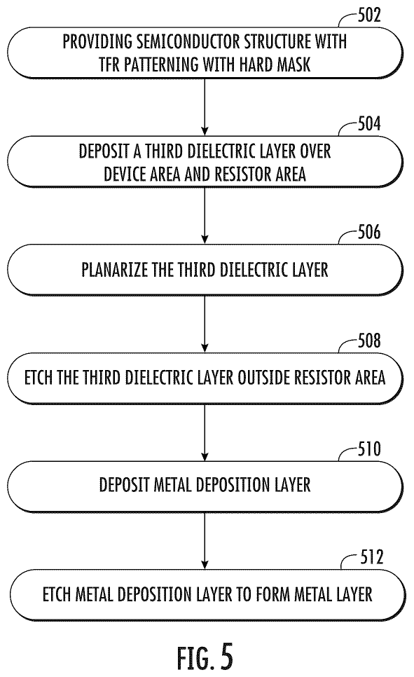

FIG. 5 illustrates a flowchart of example operations for forming a semiconductor structure in accordance with a first embodiment of the present disclosure.

At operation 502, a semiconductor structure with TFR patterning with hard mask is provided. The thin film resistor patterning is provided on a semiconductor structure, such as the exemplary semiconductor structure illustrated in FIG. 4A. The semiconductor structure may be, or may be part of, an electronic device with a back-end-of-line (BEOL) module.

At operation 504, a third dielectric layer is deposited over the device area and the resistor area. The third dielectric layer 160 is deposited over the first surface at the first level 132 and TFR patterning, including over the device area 152 and the resistor area 154. The third dielectric layer 160 includes a first sub-layer 162 that is covered by a second sub-layer 164. In various embodiments, the first sub-layer 162 is deposited first and then the second sub-layer 164 is deposited over the first sub-layer 162. In various embodiments, FIG. 4B illustrates various embodiments after the performance of operation 504.

At operation 506, the dielectric layer is planarized. The planarization of the third dielectric layer 160 flattens the top surface of the third dielectric layer 160. In various embodiments, FIG. 4C illustrates after the performance of operation 506.

At operation 508, the dielectric layer is etched outside the resistor area. The third dielectric layer 160 is etched for the device 152 and outside of the resistor area 154. In various embodiments, FIG. 4D illustrates after the performance of operation 508.

At operation 510, a metal deposition layer is deposited. The metal deposition layer 418 may be associated with the metal layer 118. The metal deposition layer 418 may be deposited over both the device area 152 and the resistor area 154. The top surface of the metal deposition layer 418 may be flat. In various embodiments, FIG. 4E illustrates after the performance of operation 510.

At operation 512, the metal deposition layer is etched to form a metal layer. The metal layer 418 is etched to form the metal layer 118. In various embodiments, FIG. 4F illustrates after the performance of operation 512. Additionally, the metal etch may remove the third dielectric layer 160 above the TFR elements 140 as well as remove some of the third dielectric layer 160 in the resistor area 154 not above the TFR elements 140.

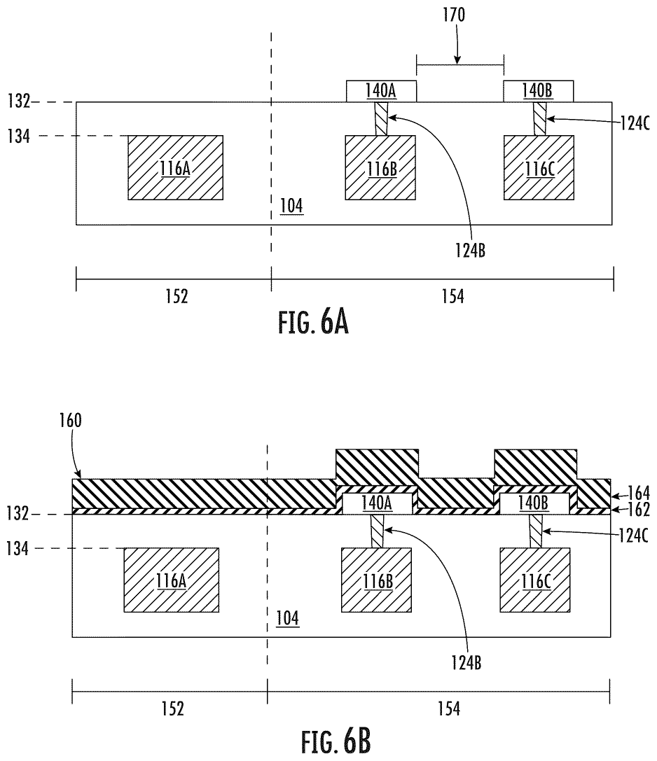

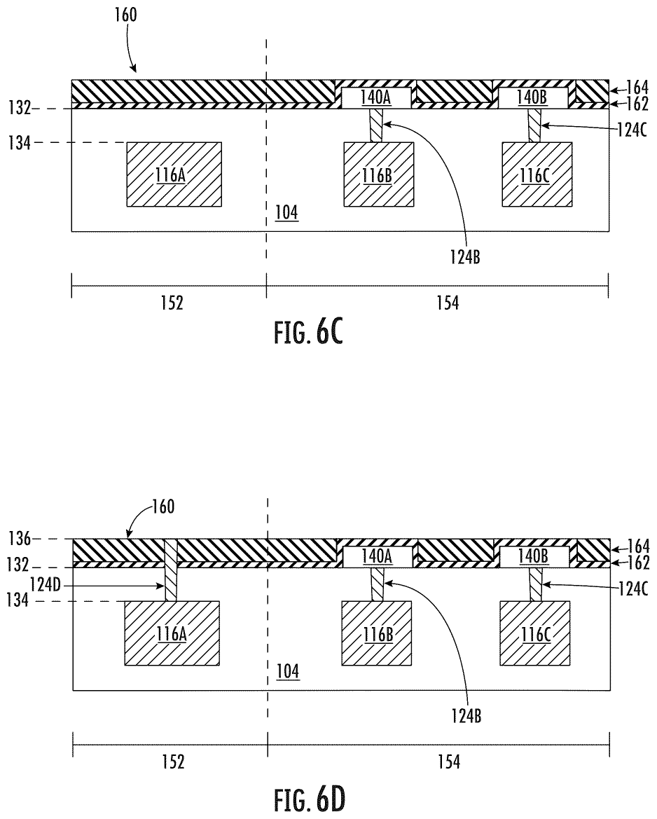

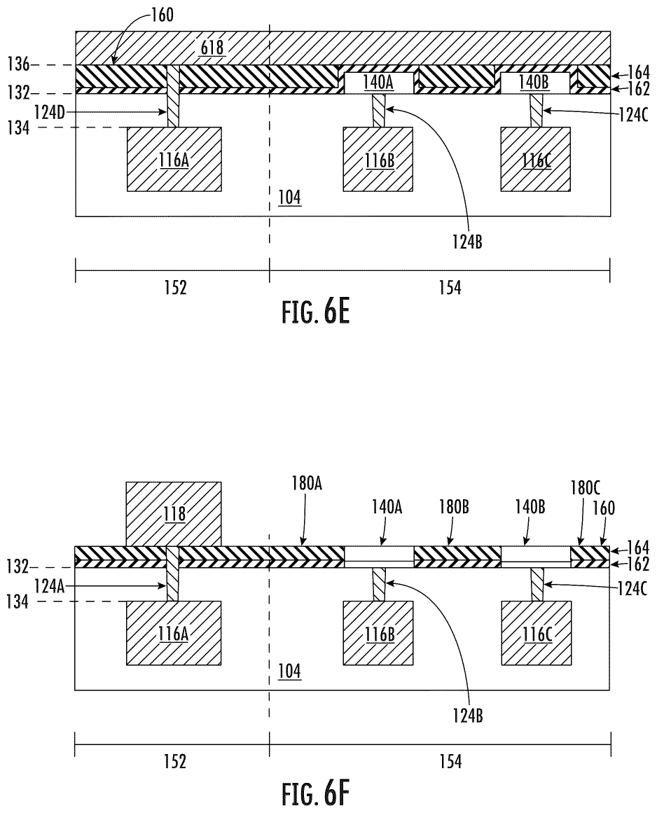

FIGS. 6A-6F illustrate exemplary cross-section views of various operations in forming a semiconductor structure in accordance with a second embodiment of the present disclosure. The semiconductor structure may be a part of an electronic device with a back-end-of-line (BEOL) module.

The structure shown in FIG. 6A is obtained performing the operations disclosed with reference to FIGS. 2A-2F, with the exception that there is no formation of via 124A (i.e., no patterning of the via cavity 124A-C on metal portion 116A and consequently no filling with tungsten (W)).

FIG. 6A illustrates a first exemplary cross-section view of an operation in forming a semiconductor structure in accordance with a second embodiment of the present disclosure. A TFR patterning with hard mask is provided. The thin film resistor patterning of the TFR layer 140L (e.g., from FIG. 2F) is provided on a semiconductor structure with a first level 132 that includes a metal layer 116 with a second level 134 electrically connected with a plurality of vias 124 (e.g., 124B, 124C) to the first level 132 of the resistor area. In the illustrated embodiment, there is no via at the device area connecting the second level 134 to the first level 132.

The thin film resistor patterning may include a first TFR element 140A and a second TFR element 140B. Each TFR element 140 (e.g., 140A, 140B) may be comprised of a resistive layer 142 and an insulating layer 144. The thin film resistor patterning may be electrically connected to one or more portions of a metal layer 116 by one or more vias 124. The TFR patterning occurred after the patterning and formation of the vias 124. A first TFR element 140A of the thin film resistor patterning may be electrically connected with a via 124B to a portion of the metal layer 116B. A second TFR element 140B of the thin film resistor patterning may be electrically connected with a via 124C to a portion of the metal layer 116C. In various embodiments, FIG. 6A is associated with operation 702.

FIG. 6B illustrates a first exemplary cross-section view of an operation in forming a semiconductor structure in accordance with a second embodiment of the present disclosure. A third dielectric layer 160 is deposited over the first surface at the first level 132 and TFR patterning. In various embodiments, the dielectric layer is comprised of a first sub-layer 162 that is covered by a second sub-layer 164, which may be referred to as a SiN/oxide layer. In various embodiments, the first sub-layer 162 is deposited first and then the second sub-layer 164 is deposited over the first sub-layer 162. In various embodiments, FIG. 6B is associated with operation 704. The thickness of the third dielectric layer 160 at this stage is thicker than the TFR element 140. In particular, the second sub-layer 164, at this stage, may have a thickness above 800 nm, preferably above 1000 nm.

FIG. 6C illustrates a first exemplary cross-section view of an operation in forming a semiconductor structure in accordance with a second embodiment of the present disclosure. The third dielectric layer 160 is planarized. The planarization may be by chemical mechanical polishing (CMP). The planarization flattens the surface of the oxide layer while exposing the first sub-layer 162 above the top of the TFR elements 140. In various embodiments, the planarization may expose the thin film resistor patterning. In various embodiments, FIG. 6C is associated with operation 706.

In various embodiments, after planarization, the first sub-layer 162 and second sub-layer 164 in the gaps between TFRs may be a first assembly of one or more portions of the resistor area 154 and a TFR element 140 and the first sub-layer 162 covering the TFR element 140 may be a second assembly. In various embodiments, a thickness of the first assembly and a respective thickness of the second assembly are both equal or within a range centered in a nominal thickness value and having −10% (preferably −5%) of the nominal thickness value as a minimum, and +10% (preferably +5%) of the nominal thickness value as a maximum. The first sub-layer may be made of a first dielectric material and the second sub-layer may be made of a second dielectric material.

FIG. 6D illustrates a first exemplary cross-section view of an operation in forming a semiconductor structure in accordance with a second embodiment of the present disclosure. A via for metal layer 118 may be formed. Forming the via may include etching the third dielectric layer 160 and the dielectric layer 104 of the device area 152 to form a cavity for patterning what will be via 124D. A deposition may occur to form via 124D in the cavity. The via 124D may electrically connect the metal layer 116 to, once it is formed, a bottom of metal layer 118, which is placed at the top of the third dielectric layer 160 at level 136. Via 124D is larger or longer than other vias 124 (e.g., 124B, 124C) that connect TFR elements 140 to the metal layer 116. In various embodiments, FIG. 6D is associated with operation 708. In this embodiment, third dielectric layer 160 remains in the device area and there is no removal by patterning, which is in contrast with embodiment in FIG. 4D above.

Consequently, as illustrated in FIG. 6D, the third dielectric layer 160 remains both in the gaps between the TFR elements 140 completely filling the spaces among them and on the device area. This creates a flat and even top surface of the semifinished product both in the resistor area and the device area. In other words, in the illustrated embodiment, the height difference created by the introduction of the TFR elements 140 is compensated by creating a longer vias for metal layer 118. As illustrated in FIG. 6D, via 124D has a height substantially given by the sum of the respective heights of vias 124B/C and the TFR elements 140 (and further the first sub-layer 162). Therefore, new level 136 is substantially flat.

FIG. 6E illustrates a first exemplary cross-section view of an operation in forming a semiconductor structure in accordance with a second embodiment of the present disclosure. A metal deposition layer 618 may be deposited over both the device area 152 and the resistor area 154. The metal deposition layer 418 may be deposited to have a (substantially) flat surface since the below surface (level 136) is (substantially) flat. In various embodiments, FIG. 6E is associated with operation 710.

FIG. 6F illustrates a first exemplary cross-section view of an operation in forming a semiconductor structure in accordance with a second embodiment of the present disclosure. The metal layer 618 is etched to form the metal layer 118. The metal layer 118 is electrically connected from below to the metal layer 116A by via 124D. Additionally, the metal etch may remove the third dielectric layer 160 above the TFR elements 140 as well as remove some of the third dielectric layer 160 in the resistor area 154 not above the TFR elements 140. In various embodiments, FIG. 6F is associated with operation 712. It is noted that third dielectric layer 160 (in particular, second sub-layer 164) remains under metal layer 118. It is possible that the height of level 164 is not uniform (due to the above patterning) in the regions among metal layer 118 and TFRs or among TFRs.

The metal layer 118 is formed by the etching of metal deposition layer 618. The etch operation removes the metal deposition layer 618 in the resistor area 154 and the first sub-layer 162 and/or the second sub-layer 164 above the TFR elements 140A, 140B. In various embodiments, the etch may create the dielectric layer between one or more TFR elements 140 being flat. Alternatively, or additionally, the etch may create the dielectric layer between one or more TFR elements 140 being concave.

The TFR elements 140 may be surrounded by one or more protective structures 180 (e.g., 180A, 180B, 180C). The one or more protective structures 180 may be located on or around the sidewalls 148 (e.g., 148A1, 148A2) of a TFR element 140 (e.g., 140A). The plurality of protective structures may be originating from the third dielectric layer 160. The plurality of protective structures 180A, 180B, 180C collectively cover each of the sidewalls of the first TFR element 140A and of the second TFR element 140B as well as the gap 170 between the first TFR element 140A and the second TFR element 140B.

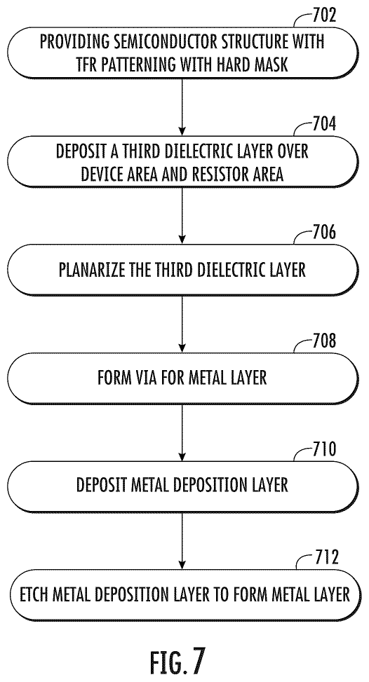

FIG. 7 illustrates a flowchart of example operations for forming a semiconductor structure in accordance with a second embodiment of the present disclosure. The semiconductor structure may be, or may be part of, an electronic device with a back-end-of-line (BEOL) module.

At operation 702, a semiconductor structure with TFR patterning with hard mask is provided. The thin film resistor patterning is provided on a semiconductor structure, such as the exemplary semiconductor structure illustrated in FIG. 6A.

At operation 704, a dielectric layer is deposited over the device area and the resistor area. The third dielectric layer 160 is deposited over the first surface at the first level 132 and TFR patterning, including over the device area 152 and the resistor area 154. The third dielectric layer 160 includes a first sub-layer 162 that is covered by a second sub-layer 164. In various embodiments, the first sub-layer 162 is deposited first and then the second sub-layer 164 is deposited over the first sub-layer 162. In various embodiments, FIG. 6B illustrates various embodiments after the performance of operation 704.

At operation 706, the dielectric layer is etched outside the resistor area. The planarization of the third dielectric layer 160 flattens the top surface of the third dielectric layer 160. In various embodiments, FIG. 6C illustrates after the performance of operation 706.

At operation 708, a via is formed for metal layer 118. Forming the via may include etching the third dielectric layer 160 and the dielectric layer 104 of the device area 152 to form a cavity for patterning what will be via 124D. A deposition may occur to form via 124D may in the cavity. In various embodiments, FIG. 6D illustrates after the performance of operation 708.

At operation 710, a metal deposition layer is deposited. The metal deposition layer 618 may be associated with the metal layer 118. The metal deposition layer 618 may be deposited over both the device area 152 and the resistor area 154. The top surface of the metal deposition layer 618 may be flat. In various embodiments, FIG. 6E illustrates after the performance of operation 710.

At operation 712, the metal deposition layer is etched to form a metal layer. The metal layer 618 is etched to form the metal layer 118. In various embodiments, FIG. 6F illustrates after the performance of operation 712. Additionally, the metal etch may remove the third dielectric layer 160 above the TFR elements 140 as well as remove some of the third dielectric layer 160 in the resistor area 154 not above the TFR elements 140.

It should be readily appreciated that the embodiments of the systems and apparatuses, described herein may be configured in various additional and alternative manners in addition to those expressly described herein.

### CONCLUSION

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a computer-implemented process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A manufacturing method of an electronic device, the method comprising:
providing a semiconductor substrate comprising a device area and a resistor area,
forming a back-end-of-line (BEOL) module overlapping the semiconductor substrate by:
forming, at both the device area and the resistor area, a first dielectric layer on the semiconductor substrate;
forming, at both the device area and the resistor area, a first metal layer on the first dielectric layer, the first metal layer comprising a plurality of metal portions;
forming, at both the device area and the resistor area, a second dielectric layer on the first metal layer;
forming, at the resistor area, a first thin film resistor (TFR) element and second TFR element on the second dielectric layer, wherein the first TFR element and the second TFR element are arranged with a gap between the first TFR element and the second TFR element, wherein the each of the first TFR element and the second TFR element are electrically contacting one or more respective metal portions of the first metal layer, and wherein each of the first TFR element and the second TFR element comprise a respective resistive layer and an insulating layer in contact with, and on, the respective resistive layer;
forming, at the resistor area, a third dielectric layer comprising:
a first sub-layer made of a first dielectric material covering both the first TFR element and the second TFR element and a portion of the second dielectric layer at the gap; and
a second sub-layer made of a second dielectric material covering the portion of the second dielectric layer interposed between the first TFR element and the second TFR element;
wherein a thickness of a first assembly of the first sub-layer and second sub-layer and a respective thickness of a second assembly of the first TFR element and the first sub-layer covering the TFR element are both within a range centered in a nominal thickness value and having −10% of the nominal thickness value as a minimum, and +10% of the nominal thickness value as a maximum;
depositing, at both the device area and the resistor area, a metal deposition layer; and
etching, at both the device area and the resistor area, the metal deposition layer to form, at the device area, a second metal layer, and, at the resistor area, a plurality of protective structures originating from the third dielectric layer, wherein the plurality of protective structures collectively cover each sidewall of the first TFR element and of the second TFR element as well as the gap between the first TFR element and the second TFR element.

2. The manufacturing method of claim 1 further comprising, before forming the first TFR element and the second TFR element, forming a first vias for electrically contacting each of the first TFR element and the second TFR element to one or more respective metal portions of the first metal layer.

3. The manufacturing method of claim 1 further comprising, before forming the first TFR element and the second TFR element, forming a second via for electrically contacting the second metal layer to one or more metal portions of the first metal layer, wherein the second via passes through the second dielectric layer, and wherein the second metal layer is on the second dielectric layer.

4. The manufacturing method of claim 1, wherein forming the third dielectric layer comprises:
i) at both the device area and the resistor area, depositing the first sub-layer;
ii) at both the device area and the resistor area, depositing the second sub-layer covering the first sub-layer over both the first TFR element and the second TFR element and the portion of the second dielectric layer at the gap; and
iii) planarizing the second sub-layer at a level corresponding to the thickness of both the first assembly and the second assembly.

5. The manufacturing method of claim 4, wherein forming the third dielectric layer further comprises, after planarizing the second sub-layer, removing the third dielectric layer at the device area.

6. The manufacturing method of claim 4, wherein forming the third dielectric layer further comprises, after planarizing the second sub-layer, leaving the third dielectric layer at the device area.

7. The manufacturing method of claim 6 further comprising, before depositing the metal deposition layer, forming a via for electrically contacting the second metal layer to a respective metal portion of the first metal layer, wherein the via passes through the second dielectric layer and the third dielectric layer, and wherein the second metal layer is on the third dielectric layer.

8. The manufacturing method of claim 1, wherein the first metal layer and the second metal layer comprise aluminum.

9. The manufacturing method of claim 1, wherein the resistive layer comprises a SiCr layer, and the insulating layer comprises a SiN layer.

10. The manufacturing method of claim 1, wherein the BEOL module comprises a number N of metal layers, wherein an N-th metal layer is the farthermost from the semiconductor substrate, and the second metal layer is the N-th metal layer.

11. A semiconductor structure comprising:
a semiconductor substrate comprising a device area and a resistor area,
a back-end-of-line (BEOL) module overlapping the semiconductor substrate and comprising:
at both the device area and the resistor area, a dielectric layer on the semiconductor substrate;
at both the device area and the resistor area, a first metal layer comprising a plurality of metal portions, the first metal layer positioned in the dielectric layer at a first height;
at the resistor area, a first thin film resistor (TFR) element and second TFR element, wherein the first TFR element and the second TFR element are arranged with a gap between the first TFR element and the second TFR element, wherein the each of the first TFR element and the second TFR element are electrically contacting one or more respective metal portions of the first metal layer, wherein each of the first TFR element and the second TFR element comprise a respective resistive layer and an insulating layer in contact with, and on, the respective resistive layer, and wherein the first TFR element and the second TFR element are positioned in the dielectric layer at a second height greater than the first height;
at the device area, a second metal layer electrically contacting respective portions of the first metal layer and positioned at the second height; and
at the resistor area, a plurality of protective structures, wherein the plurality of protective structures collectively covers each sidewall of the first TFR element and of the second TFR element as well as the gap between the first TFR element and the second TFR element.

12. The semiconductor structure of claim 11, wherein the protective structures and the first TFR element and the second TFR element have substantially a flat surface.

13. The semiconductor structure of claim 11 further comprising:
first vias for electrically contacting each of the first TFR element and the second TFR element with one or more of the metal portions of the first metal layer;
a second via for electrically contacting the second metal layer and one or more metal portions of the first metal layer; and
wherein the first vias and the second via have a same height.

14. The semiconductor structure of claim 11, wherein the first metal layer and the second metal layer comprise aluminum.

15. The semiconductor structure of claim 11, wherein the BEOL module comprises a number N of metal layers, wherein an N-th metal layer is the farthermost from the semiconductor substrate, and the second metal layer is the N-th metal layer.

16. A semiconductor structure comprising:
a semiconductor substrate comprising a device area and a resistor area,
a back-end-of-line, BEOL, module overlapping the semiconductor substrate and comprising:
at both the device area and the resistor area, a dielectric layer on the semiconductor substrate;
at both the device area and the resistor area, a first metal layer comprising a plurality of metal portions, the first metal layer positioned in the dielectric layer at a first height;
at the resistor area, a first thin film resistor (TFR) element and second TFR element, wherein the first TFR element and the second TFR element are arranged with a gap between the first TFR element and the second TFR element, wherein the each of the first TFR element and the second TFR element are electrically contacting one or more respective metal portions of the first metal layer, wherein each of the first TFR element and the second TFR element comprise a respective resistive layer and an insulating layer in contact with, and on, the respective resistive layer, and wherein the first TFR element and the second TFR element are positioned in the dielectric layer at a second height greater than the first height;
at the device area, a second metal layer electrically contacting respective portions of the first metal layer and positioned at a third height greater than the second height; and
at the resistor area, a plurality of protective structures, wherein the plurality of protective structures collectively covers each sidewall of the first TFR element and of the second TFR element as well as the gap between the first TFR element and the second TFR element.

17. The semiconductor structure of claim 16, wherein the protective structures and the first TFR element and the second TFR element have substantially a flat surface.

18. The semiconductor structure of claim 16 further comprising:
first vias for electrically contacting each of the first TFR element and the second TFR element with one or more of the metal portions of the first metal layer;
a second via for electrically contacting the second metal layer and one or more metal portions of the first metal layer; and
wherein the first vias are shorter than the second via.

19. The semiconductor structure of claim 16, wherein the first metal layer and the second metal layer comprise aluminum.

20. The semiconductor structure of claim 16, wherein the BEOL module comprises a number N of metal layers, wherein an N-th metal layer is the farthermost from the semiconductor substrate, and the second metal layer is the N-th metal layer.
